(19) United States
(12) Patent Application Publication
(10) Pub. No.: US 2026/0266903 A1
(43) Pub. Date: Sep. 10, 2026

(54) CONFIGURABLE TEST CIRCUIT

(71) Applicant: Hewlett Packard Enterprise Development LP, Spring, TX (US)

(72) Inventors: Curtis Love Purnell, Rosenberg, TX (US); Mujeeb Rehman, Cypress, TX (US)

(21) Appl. No.: 19/075,514

(22) Filed: Mar. 10, 2025

(51) Int. Cl. G01R 31/3177; G01R 31/317

(52) U.S. Cl. CPC G01R 31/3177; G01R 31/31705

(57) ABSTRACT

According to an implementation, a configurable test circuit enables identical host processor motherboards to support Joint Test Action Group (JTAG) debugging across multiple operating configurations. Each motherboard includes a processor socket, a JTAG header, a transceiver coupled between the JTAG header and processor socket, multiplexers coupled between the processor socket and a connector interface, and a control circuit. In a single processor configuration, JTAG signals route from the header through the processor socket and return to the header. In a dual processor configuration, two identical motherboards couple through their connector interfaces, where one processor functions as a bootstrap processor (BSP) while the other operates as an application processor (AP). The control circuit configures the multiplexers to create a debug chain from the BSP motherboard's JTAG header through both processors.

### BACKGROUND

High-performance computing systems employ modular motherboard designs that support flexible processor configurations. These motherboards include processor sockets, memory interfaces, and debugging capabilities through standardized Joint Test Action Group (JTAG) test access ports. JTAG interfaces enable system developers to examine processor registers, set breakpoints, and analyze processor operations during the development and testing phases.

In multi-processor configurations, JTAG signals follow specific routing paths through the processors to maintain debug chain integrity. The debug chain typically starts at a JTAG header, passes through each processor sequentially, and returns to the original header. This allows system developers to access and monitor all processors in the system through a single debug interface during testing and validation procedures.

### BRIEF DESCRIPTION OF THE DRAWINGS

For a more complete understanding of this disclosure, and advantages thereof, reference is now made to the following descriptions taken in conjunction with the accompanying drawings, in which:

FIG. 1 is a block diagram of an implementation host processor motherboard;

FIG. 2 is a block diagram of a system that includes a first host processor motherboard and a second host processor motherboard coupled with a cable connection;

FIG. 3 is a block diagram of an implementation host processor motherboard, which can be implemented as the first host processor motherboard or the second host processor motherboard of FIG. 2;

FIG. 4 is a flowchart of an implementation method for operating the host processor motherboard in a single processor configuration (i.e., 1P node configuration);

FIG. 5 is a flowchart of an implementation method for operating the host processor motherboard as a BSP motherboard in the dual motherboard configuration shown in FIG. 2;

FIG. 6 is a flowchart of an implementation method for operating the host processor motherboard as an AP motherboard in the dual motherboard configuration shown in FIG. 2; and

FIG. 7 is a flowchart of an implementation method for operating the host processor motherboard in a test configuration.

### DESCRIPTION

The following disclosure provides many different examples for implementing different features. Specific examples of components and arrangements are described below to simplify the present disclosure. These are, of course, merely examples and are not intended to be limiting.

The particular implementations are merely illustrative of specific configurations and do not limit the scope of the claimed implementations. Features from different implementations may be combined to form further examples unless noted otherwise. Various implementations are illustrated in the accompanying drawing figures, where identical components and elements are identified by the same reference number, and repetitive descriptions are omitted for brevity.

Variations or modifications described in one of the implementations may also apply to others. Further, various changes, substitutions, and alterations can be made herein without departing from the spirit and scope of this disclosure as defined by the appended claims.

While the aspects are described primarily in the context of host processor motherboards with Joint Test Action Group (JTAG) debug capabilities for server systems, it should also be appreciated that these aspects may also apply to other computing platforms utilizing processor debug interfaces. In particular, aspects of the disclosure may similarly apply to workstation computers, embedded systems, network devices, storage systems, or any computing system that employs processor-based debug chains for testing and validation.

In implementations, a configurable test circuit enables identical host processor motherboards to support JTAG debugging across multiple operating configurations. Each motherboard includes a processor socket, a JTAG header for test access, a first set of multiplexers coupled between the JTAG header and processor socket, a second set of multiplexers coupled between the processor socket and a connector interface, and a control circuit coupled to both sets of multiplexers.

The control circuit configures the multiplexers to establish appropriate JTAG signal paths based on the operating mode. In a single processor configuration, JTAG signals route from the header through the processor socket and return to the header. The first set of multiplexers can bypass an empty processor socket to maintain signal continuity when no processor is present. The second set of multiplexers may isolate the connector interface when operating in single processor mode.

For dual processor configurations, two identical motherboards couple through their connector interfaces. One processor functions as a bootstrap processor (BSP) while the other operates as an application processor (AP). The control circuit on the BSP motherboard configures its multiplexers to create a debug chain from the JTAG header through both processors. JTAG signals flow from the BSP motherboard's header, through its processor socket, across the connector interface to the AP motherboard's processor socket, and return to the BSP motherboard's header via the connector interface.

In implementations, the control circuit includes programmable logic that sets multiplexer configurations according to the operating mode. This arrangement provides complete debug access through a single JTAG interface, using identical motherboard designs for both BSP and AP roles. These and additional details are further discussed below.

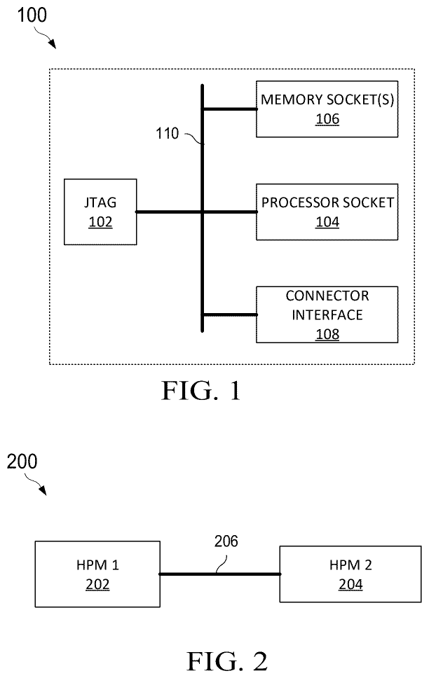

FIG. 1 illustrates a block diagram of an implementation host processor motherboard 100. Host processor motherboard 100 includes a Joint Test Action Group (JTAG) header 102 for providing test access, a processor socket 104 for receiving a processor, one or more memory sockets 106 for receiving memory devices, and a connector interface 108 for coupling to another host processor motherboard. The components are coupled through a main interconnect bus 110.

JTAG header 102 provides an interface for external test equipment to access debug features of a processor when seated in processor socket 104. Memory socket(s) 106 can accommodate one or more memory devices to provide system memory for the processor. Connector interface 108 includes signal paths that enable host processor motherboard 100 to couple with a second host processor motherboard through a cable to form a dual-processor configuration.

Host processor motherboard 100 may include additional components not shown in FIG. 1, such as power management circuitry, additional interfaces, and other supporting circuitry. The arrangement and number of components shown in FIG. 1 represent one possible implementation, and other implementations may include different arrangements or additional components.

JTAG header 102 provides standardized test access ports for debugging processors through industry-standard JTAG protocols. In a single processor configuration, JTAG header 102 can couple directly to processor socket 104 to enable testing and debugging of the local processor. The JTAG signals can include test data input (TDI), test data output (TDO), test mode select (TMS), and test clock (TCK) lines that allow external test equipment to control the processor's test modes and access internal registers.

When the host processor motherboard 100 operates in a dual processor configuration, JTAG header 102 serves as the main debug interface for both processors. If the local processor operates as a bootstrap processor (BSP), JTAG header 102 initiates the debug chain by sending signals through the local processor before routing to the second processor. If the local processor operates as an application processor (AP), JTAG header 102 remains inactive while debug signals route through the connector interface 108 from the BSP motherboard.

Processor socket 104 provides mechanical and electrical connections for a processor. The socket supports installing and removing processors to enable testing with different processor configurations or bypassing an unpopulated socket. In single processor mode, a processor in the processor socket 104 handles all computing tasks independently. The processor can access local memory through memory sockets 106 without requiring coordination with other processors.

In dual processor configurations, the processor in processor socket 104 operates either as a BSP or an AP based on system requirements. As a BSP, the processor manages system initialization and coordinates with the AP on the second motherboard. As an AP, the processor receives initialization parameters from the BSP and operates as a supplementary processing resource. The socket includes additional signal paths to support inter-processor communication through connector interface 108.

Memory socket(s) 106 accommodate memory devices that provide system memory capacity. In single processor configurations, all memory devices couple to the local processor through memory socket(s) 106. The processor can utilize the full memory capacity without sharing or coordination requirements.

For dual processor configurations, memory socket(s) 106 may participate in a shared memory architecture. Both the BSP and AP processors can access memory devices across both motherboards through the high-speed interconnects in connector interface 108. The memory configuration supports cache coherency and coordinated memory access between the processors.

Connector interface 108 enables host processor motherboard 100 to couple with a second motherboard through a cable connection. In single processor mode, connector interface 108 remains inactive. The interface includes high-speed serial lanes for processor-to-processor communication, memory access paths, power distribution, and JTAG signal routing between boards.

Connector interface 108 can provide signal paths between the motherboards when operating in dual processor mode. For BSP operation, the interface routes JTAG signals from the local processor to the AP processor on the second board. In AP operation, the interface receives JTAG signals from the BSP board and returns test data through the same path. The interface maintains signal integrity across the cable connection to ensure reliable communication between the processors.

Main interconnect bus 110 provides the main interconnect structure between components on the host processor motherboard 100. The bus includes dedicated paths for JTAG signals between JTAG header 102, processor socket 104, and connector interface 108. Additional paths can support memory access, power distribution, and other system functions. Main interconnect bus 110 maintains consistent signal routing regardless of the processor configuration or operating mode.

FIG. 2 illustrates a block diagram of a system 200 that includes a first host processor motherboard 202 and a second host processor motherboard 204 coupled with a cable connection 206. The first host processor motherboard 202 and the second host processor motherboard 204 have a configuration identical to host processor motherboard 100, as shown in FIG. 1. Cable connection 206 couples the connector interface 108 of first host processor motherboard 202 to the connector interface 108 of second host processor motherboard 204.

In this dual processor configuration, the first host processor motherboard 202 and the second host processor motherboard 204 operate together as a 2P node. The processor in the first host processor motherboard 202 functions as a bootstrap processor (BSP) that handles system initialization, while the processor in the second host processor motherboard 204 functions as an application processor (AP). Though shown with first host processor motherboard 202 as the BSP, the motherboards are identical, and their roles can be reversed based on system configuration requirements.

Cable connection 206 provides signal paths for JTAG debug chains between the motherboards. JTAG signals can originate from the JTAG header of first host processor motherboard 202, route through its processor, traverse cable connection 206 to reach the processor on the second host processor motherboard 204, and return via cable connection 206 back to the JTAG header on the first host processor motherboard 202. This configuration enables the debugging of both processors through a single JTAG interface on the BSP motherboard.

Cable connection 206 can also carry additional signals between the motherboards, such as inter-processor communication paths, shared memory access, power distribution, and control signals. High-speed serial lanes in cable connection 206 can maintain signal integrity across the physical distance between the motherboards while supporting the bandwidth requirements of dual-processor operation.

When operating as a 2P node, system 200 can maintain debug capabilities even if one or both processor sockets are unpopulated. The multiplexer arrangements on each motherboard can automatically bypass an empty processor socket while maintaining the JTAG chain integrity through cable connection 206.

For example, each motherboard's control circuit can detect the operating mode and processor presence to configure the appropriate signal paths. If the AP processor is absent, JTAG signals from the BSP motherboard's processor route through the cable connection 206 and return without traversing through the empty AP socket. This flexibility enables the testing of various processor configurations and system validation scenarios.

In the 2P node configuration, the memory sockets on both motherboards can form a unified memory architecture. Cable connection 206 can include dedicated paths that allow each processor to access memory devices on either motherboard. The BSP can initialize and configure the memory subsystem across both motherboards during system startup, enabling coordinated memory access and cache coherency between the processors during operation.

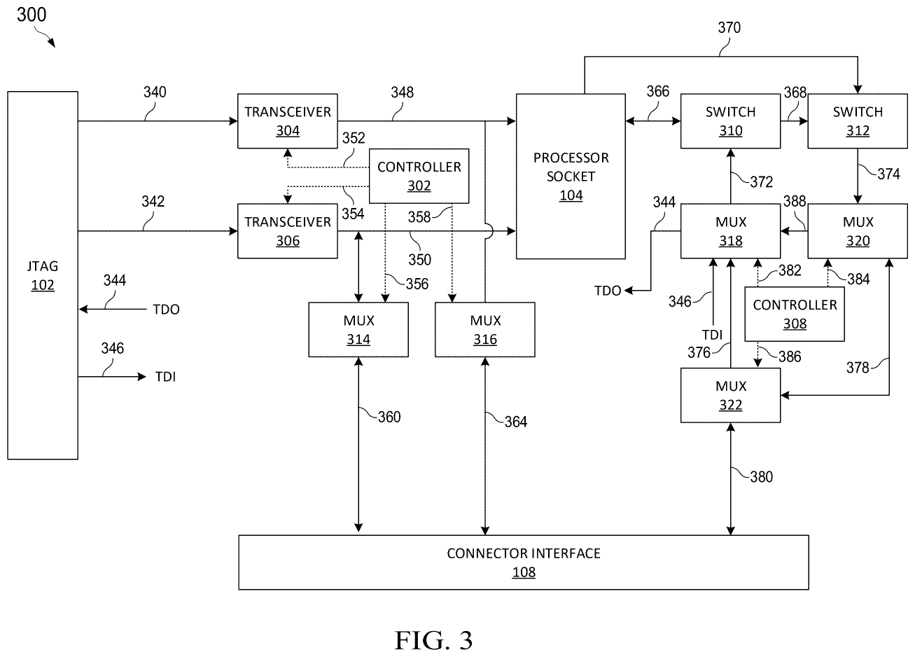

FIG. 3 is a block diagram of an implementation host processor motherboard 300, which can be implemented as the first host processor motherboard 202 or the second host processor motherboard 204 of FIG. 2. Host processor motherboard 300 includes the JTAG header 102, the processor socket 104, a first controller 302, a first transceiver 304, a second transceiver 306, a first switch 310, a second switch 312, a first multiplexer 314, a second multiplexer 316, a third multiplexer 318, a fourth multiplexer 320, a fifth multiplexer 322, a second controller 308, and the connector interface 108, which may (or may not) be arranged as shown.

Host processor motherboard 300 may include additional components not shown—to simplify the discussion, such as the memory socket 106, power management circuitry, additional interfaces, and supporting circuitry. The arrangement and number of components shown in FIG. 3 represent one possible implementation, and other implementations may include different arrangements or additional components.

In implementations, the second transceiver 306 and second multiplexer 316 shown in FIG. 3 can be optional, as their sideband signal handling functions can be performed by the first transceiver 304 and third multiplexer 318. The signal paths 342 and 350 for sideband signals can be routed through the first transceiver 304 and third multiplexer 318 along with the main JTAG signals.

JTAG header 102 provides external test signals for sending test data input (TDI) into the debug chain, receiving test data output (TDO) from the debug chain, synchronizing the test logic, controlling the test access port state machine, initializing the test logic, initiating debug operations, or the like.

In implementations, the main JTAG signals are routed to the first transceiver 304 through the signal path 340, while sideband signals are routed to the second transceiver 306 through the signal path 342. The main JTAG signals can include the test clock (TCK) for synchronizing the test logic, a test mode select (TMS) signal for controlling the access port state machine, a test reset (TRST) signal for initializing the test logic, a debug request (DBREQ_N) signal for initiating debug operations, or a combination thereof. The sideband signals can be auxiliary JTAG control signals that, for example, manage test operations. These sideband signals work in conjunction with the test data input (TDI) signal and the test data output (TDO) signal to enable coordinated testing and debugging operations.

First controller 302 manages signal routing between JTAG header 102 and the processor socket 104 by enabling the first transceiver 304 and the second transceiver 306. In implementations where the host processor motherboard 300 is configured as a dual motherboard, the first controller 302 manages signal routing between the JTAG header 102 and the connector interface 108 through the first multiplexer 314 and the second multiplexer 316.

In implementations, the first controller 302 manages the signal routing within the host processor motherboard 300 through a first control signal path 352 provided to the first transceiver 304, a second control signal path 354 provided to the second transceiver 306, a third control signal path 356 to the first multiplexer 314, and a fourth control signal path 358 to the second multiplexer 316.

Second controller 308 manages signal routing between processor socket 104 and connector interface 108 and between the processor socket 104 and the JTAG header 102. In implementations where the host processor motherboard 300 is configured as a dual motherboard, the second controller 308 manages signal routing between the connector interface 108 and the JTAG header 102 through the third multiplexer 318, the fourth multiplexer 320, and the fifth multiplexer 322.

In implementations, the second controller 308 manages the signal routing within the host processor motherboard 300 through a fifth control signal path 382 provided the third multiplexer 318, a sixth control signal path 384 to the fourth multiplexer 320, and a seventh control signal path 386 to the fifth multiplexer 322.

The first controller 302 and the second controller 308 can be implemented using, for example, programmable logic devices such as Field Programmable Gate Arrays (FPGAs) or Complex Programmable Logic Devices (CPLDs). The first controller 302 can include programmable logic that sets multiplexer configurations according to the operating mode of the host processor motherboard 300—whether operating in single processor mode or as part of a dual processor configuration as either a BSP or AP.

Similarly, the second controller 308 can include programmable logic for configuring the multiplexer network between the processor socket 104 and the connector interface 108. In implementations, the controllers can automatically detect processor presence and configure appropriate signal paths to maintain JTAG chain integrity, including bypassing empty processor sockets when processors are not present.

While FIG. 3 illustrates the first controller 302 and the second controller 308 as separate components to simplify the discussion of their respective functions, these controllers can be implemented as a single programmable logic device that manages all multiplexer configurations and signal routing paths on the host processor motherboard 300. This single controller implementation can provide the same functionality while potentially reducing component count and simplifying board design.

Likewise, the transceivers and multiplexers can be implemented as a single device that manages all configurations and signal routing paths on the host processor motherboard 300. The single device implementation can provide the same functionality while potentially reducing component count and simplifying board design.

The transceivers, switches, and multiplexers provide signal isolation and routing control based on operating mode. For example, the multiplexers provide configurable signal routing paths depending on the configuration of the host processor motherboard 300.

The processor socket 104 includes test data input (TDI) and test data output (TDO) connections for JTAG signals. In implementations, signal path 366 carries TDO from the processor socket 104 to the second switch 312. In implementations where the processor is absent from the processor socket 104, signal path 370 provides a control signal for the second switch 312 to determine the routing of signals through the host processor motherboard 300.

Although FIG. 3 illustrates single signal paths between various components, it should be understood that each signal path can carry multiple signals. For example, signal path 340 can carry multiple main JTAG signals including test clock (TCK), test mode select (TMS), test reset (TRST), and debug request (DBREQ_N) signals. Similarly, other signal paths shown in FIG. 3 may represent multiple physical connections between components that carry multiple signals simultaneously. The single lines simplify the illustration and discussion of signal routing through the host processor motherboard 300.

The connector interface 108 provides signal paths to couple the host processor motherboard 300 with another identical motherboard. The connector interface 108 includes dedicated paths for JTAG signals processed through the multiplexer networks, enabling configurable debug chains across multiple motherboards.

The host processor motherboard 300 can support multiple operating configurations. In a single processor configuration, it operates independently, with its processor functioning as a bootstrap processor (BSP). In a dual processor configuration, two identical host processor motherboards are coupled through their connector interfaces 108. In each of the dual processor configurations, one motherboard operates as the BSP motherboard while the other operates as an application processor (AP) motherboard. Accordingly, the host processor motherboard 300 can operate as either a bootstrap processor (BSP) motherboard or an application processor (AP) motherboard. The signal routing and multiplexer configurations for each operating mode are detailed below.

Although FIG. 3 shows the host processor motherboard 300 with a first transceiver 304 and a second transceiver 306, in implementations of the disclosure, these components can be implemented using switches, buffers, or other signal routing and conditioning circuits that provide similar functionality for managing JTAG signal paths between the JTAG header 102 and other components.

Similarly, while the first switch 310, the second switch 312, the first multiplexer 314, the second multiplexer 316, the third multiplexer 318, the fourth multiplexer 320, and the fifth multiplexer 322 are shown as separate components, embodiments of the disclosure can implement these signal routing functions using different combinations of switches, multiplexers, or other signal routing circuits that achieve the same signal path control capabilities.

The specific choice of transceivers, switches, multiplexers, or other components can be selected based on factors such as signal integrity requirements, power consumption, and board layout considerations while maintaining the same overall signal routing capabilities described above.

In implementations, the first controller 302 and second controller 308 can include or be coupled to non-transitory computer-readable media storing instructions that, when executed, cause the controllers to perform their respective configuration and signal routing functions. The non-transitory computer-readable media can include ROM, RAM, magnetic disk storage media, optical storage media, flash memory devices, or other storage devices suitable for storing control instructions. When executed by the controllers, these stored instructions configure the various multiplexers, switches, and signal paths according to the detected operating mode of the host processor motherboard 300.

In some implementations, the first controller 302 and second controller 308 can be implemented using Field Programmable Gate Arrays (FPGAs) coupled to external non-transitory computer-readable media such as ROM, flash memory, or other persistent storage devices.

The FPGAs can incorporate programmable logic blocks and programmable interconnects that can be configured based on instructions stored in the non-transitory computer-readable media. Upon system initialization, the configuration data from the non-transitory storage can be loaded into the FPGA's configuration memory to establish the control logic for managing the multiplexers, switches, and signal paths according to the detected operating mode of the host processor motherboard 300.

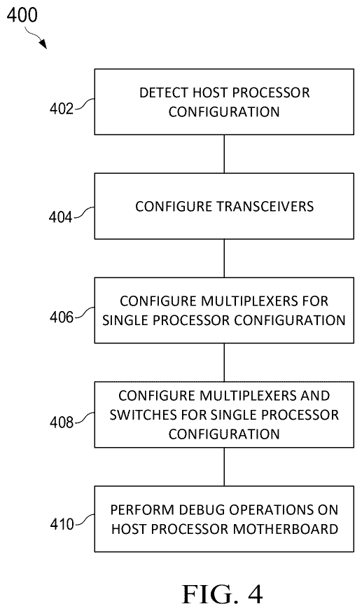

FIG. 4 illustrates a flowchart of an implementation method 400 for operating the host processor motherboard 300 in a single processor configuration (i.e., 1P node configuration). It is noted that all steps outlined in the method are not necessarily required and can be optional. Further, changes to the arrangement of the steps, removal of one or more steps and path connections, and addition of steps and path connections are similarly contemplated.

In a single processor configuration, the host processor motherboard 300 operates independently with a single processor. In implementations where the processor is present, it functions as a bootstrap processor (BSP) that handles all processing tasks. The JTAG header 102 provides direct debug access to this processor without requiring signal routing to other motherboards.

At step 402, the first controller 302 and the second controller 308, in combination or individually, detect that the host processor motherboard 300 is operating in a single processor configuration. This detection can be based on configuration settings stored in the controllers, the absence of signals from the connector interface 108, or hardware strapping options on the motherboard. In some implementations, the controllers can receive a signal (not shown) from the JTAG header 102 that indicates the test configuration.

The configuration detection process can begin when the JTAG master software initializes, and the system exits the reset state. In implementations, the first controller 302 and second controller 308 do not directly control test operations but rather configure signal routing paths based on cable detection at connector interface 108.

External test equipment coupled to JTAG header 102 can execute the test procedures. The controllers can monitor signals from a cable coupled to connector interface 108, where the cable design can incorporate, for example, an asymmetrical grounding scheme—one end includes grounded signals while the other end remains ungrounded. When connected, the motherboard receiving the grounded cable signals can operate as the second host processor motherboard 204 (AP motherboard), while the motherboard receiving ungrounded signals can function as the first host processor motherboard 202 (BSP motherboard).

In embodiments, the controllers can be configured to monitor a cable presence signal. In the absence of a cable connection at connector interface 108, the controllers can configure the host processor motherboard 300 to operate in standalone mode with a single processor.

At step 404, depending on the determination at step 402, the first controller 302 configures the first transceiver 304 and the second transceiver 306 to enable JTAG signal routing from the JTAG header 102 to the processor socket 104, the first multiplexer 314, and the second multiplexer. The first transceiver 304 receives the main JTAG signals from the JTAG header 102 through signal path 340 and forwards them to the processor socket 104 and the second multiplexer 316 through signal path 348. The second transceiver 306 forwards the sideband signals received via signal path 342 and forwards them to the processor socket 104 and the first multiplexer 314 through signal path 350. In embodiments, the first controller 302 disables the first transceiver 304 and the second transceiver in response to determining that there is no processor present in the processor socket 104 of the host processor motherboard 300.

At step 406, the first controller 302 configures the first multiplexer 314 and the second multiplexer 316 to isolate the connector interface 108 since no second motherboard is present in the single processor configuration. The first controller 302 sets the third control signal path 356 and the fourth control signal path 358 to configure the first multiplexer 314 and the second multiplexer 316, respectively, to prevent JTAG signals from routing to the connector interface 108. This isolation ensures that electrical noise or floating signals from the unused connector interface do not interfere with the JTAG debug chain between the JTAG header 102 and the processor socket 104.

At step 408, the second controller 308 configures the third multiplexer 318, the fourth multiplexer 320, and the fifth multiplexer 322 to establish the JTAG debug chain. The third multiplexer 318 is the main routing point for TDI and TDO signals from and to the JTAG header 102.

In implementations where the processor is present in the processor socket 104, the test data input (TDI) signal is routed from the JTAG header 102 through the signal path 346 to the third multiplexer 318, through signal path 372 to the first switch 310, and finally through signal path 366 to the processor socket 104. The test data output (TDO) signal returns from the processor socket 104 through the signal path 370 to second switch 312, through the signal path 370 to the fourth multiplexer 320, through signal path 388 to the third multiplexer 318, and back to the JTAG header 102 through signal path 344.

In implementations where the processor is absent from the processor socket 104, the test data input (TDI) signal is routed from the JTAG header 102 through the signal path 346 to the third multiplexer 318, through signal path 372 to the first switch 310. The second controller 308 configures the first switch 310 and the second switch 312 to create a bypass path. Accordingly, in the absence of the processor, the test data input (TDI) signal is provided as the test data output (TDO) signal to the second switch 312 through the signal path 368, through the signal path 374 to the fourth multiplexer 320, through signal path 388 to the third multiplexer 318, and back to the JTAG header 102 through signal path 344. This bypass path maintains JTAG chain continuity even with an empty processor socket. This allows testing of other components on the motherboard even when the processor socket is unpopulated.

At step 410, with the JTAG debug chain established, debug operations can be performed through the JTAG header 102. In implementations where the processor is present in the processor socket 104, these operations may include examining processor registers, setting breakpoints, analyzing processor operations, or performing other debug functions. The test clock (TCK) synchronizes the debug operations, while the test mode select (TMS) signal controls the test access port state machine. Test data is sent through the TDI signal path and results are received through the TDO signal path. In implementations where the processor is absent, the established bypass path allows for testing of other components on the host processor motherboard 300 through the same JTAG interface.

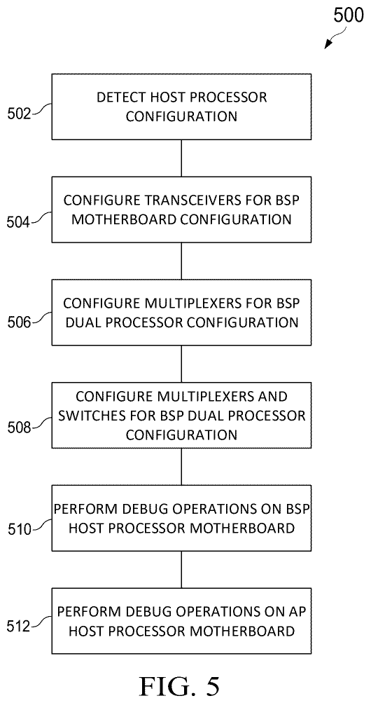

FIG. 5 illustrates a flowchart of an implementation method 500 for operating the host processor motherboard 300 as a BSP motherboard in the dual motherboard configuration shown in FIG. 2. It is noted that all steps outlined in the method are not necessarily required and can be optional. Further, changes to the arrangement of the steps, removal of one or more steps and path connections, and addition of steps and path connections are similarly contemplated.

When operating as a BSP motherboard, the host processor motherboard 300 serves as the first host processor motherboard 202 that initiates the debug chain through the BSP and AP motherboards. The JTAG header 102 on the BSP motherboard provides the single debug interface for both motherboards, with JTAG signals traversing through the local processor in the processor socket 104 before routing to and from the AP motherboard through the connector interface 108.

At step 502, the first controller 302 and the second controller 308, in combination or individually, detect whether the host processor motherboard 300 is operating in a dual processor configuration. This detection can be based on configuration settings stored in the controllers, the absence of signals from the connector interface 108, or hardware strapping options on the motherboard. The detecting additionally includes determining whether the host processor motherboard 300 is operating as the first host processor motherboard 202 (BSP motherboard) or the second host processor motherboard 204 (AP motherboard). In some implementations, the controllers can receive a signal (not shown) from the JTAG header 102 that indicates the test configuration.

At step 504, depending on the determination at step 502, the first controller 302 configures the first transceiver 304 and the second transceiver 306 to enable JTAG signal routing from the JTAG header 102 to the processor socket 104, the first multiplexer 314, and the second multiplexer. The first transceiver 304 receives the main JTAG signals from the JTAG header 102 through signal path 340 and forwards them to the processor socket 104 and the second multiplexer 316 through signal path 348. The second transceiver 306 forwards the sideband signals received via signal path 342 and forwards them to the processor socket 104 and the first multiplexer 314 through signal path 350. In embodiments, the first controller 302 disables the first transceiver 304 and the second transceiver in response to determining that there is no processor present in the processor socket 104 of the host processor motherboard 300.

At step 506, the first controller 302 configures the first multiplexer 314 and the second multiplexer 316 to route the main JTAG signals and the sideband signals to the connector interface 108, which is coupled to the second host processor motherboard 204. The first controller 302 sets the third control signal path 356 and the fourth control signal path 358 to configure the first multiplexer 314 and the second multiplexer 316, respectively, to allow JTAG signals to be routed to the connector interface 108.

At step 508, the second controller 308 configures the third multiplexer 318, the fourth multiplexer 320, and the fifth multiplexer 322 to establish the JTAG debug chain. The third multiplexer 318 of the BSP motherboard is the main routing point for TDI and TDO signals from and to the JTAG header 102.

In implementations where the processor is present in the processor socket 104, the test data input (TDI) signal is routed from the JTAG header 102 through the signal path 346 to the third multiplexer 318, through signal path 372 to the first switch 310, and finally through signal path 366 to the processor socket 104. The test data output (TDO) signal returns from the processor socket 104 through the signal path 370 to second switch 312. The TDO signal from the BSP processor of the BSP motherboard is routed through the multiplexer network through connector interface 108 as the test data input (TDI) signal for the AP motherboard.

The BSP processor's TDO signal is routed from the second switch 312 to the fourth multiplexer 320 through signal path 374, from the fourth multiplexer 320 to the fifth multiplexer 322 through signal path 378, and from the fifth multiplexer 322 to the connector interface 108 through signal path 380. The signal serves as the TDI signal for the AP motherboard.

The AP motherboards test data output (TDO) signal is received at the connector interface 108 and routed to the fifth multiplexer 322, which routes the signal to the third multiplexer 318 through the signal path 376, which is then routed to the JTAG header 102 from the third multiplexer 318 through the signal path 344.

In implementations where the processor is absent from the processor socket 104, the test data input (TDI) signal is routed from the JTAG header 102 through the signal path 346 to the third multiplexer 318, through signal path 372 to the first switch 310. The second controller 308 configures the first switch 310 and the second switch 312 to create a bypass path. Accordingly, in the absence of the processor, the AP motherboard's test data input (TDI) is provided as the test data output (TDO) signal to the second switch 312. The TDO signal, which has bypassed the processor socket 104 in the AP motherboard, is routed through the multiplexer network through connector interface 108 as the test data input (TDI) signal for the AP motherboard.

The BSP motherboard's TDO signal is routed from the second switch 312 to the fourth multiplexer 320 through signal path 374, from the fourth multiplexer 320 to the fifth multiplexer 322 through signal path 378, and from the fifth multiplexer 322 to the connector interface 108 through signal path 380. The signal serves as the TDI signal for the AP motherboard.

The AP motherboards test data output (TDO) is received at the connector interface and routed to the fifth multiplexer 322, which routes the signal to the third multiplexer 318 through the signal path 376, which is routed to the JTAG header 102 from the third multiplexer 318 through the signal path 344.

At step 510, with the JTAG debug chain established through both motherboards, debug operations can be performed on the BSP and AP motherboards through the JTAG header 102 of the BSP motherboard. In implementations where the BSP processor is present in the processor socket 104, these operations may include examining processor registers, setting breakpoints, analyzing processor operations, or performing other debug functions on the BSP processor. The test clock (TCK) synchronizes the debug operations, while the test mode select (TMS) signal controls the test access port state machine. Test data is sent through the TDI signal path, and results are received through the TDO signal path. In implementations where the BSP processor is absent, the established bypass path allows testing to continue to the AP processor.

At step 512, debug operations continue to the AP motherboard via the connector interface 108. The TDI signals that traversed through (or bypassed) the BSP processor now enter the AP motherboard for debug operations. The AP motherboard's test responses return through the TDO path back to the JTAG header 102 of the BSP motherboard. This single debug interface approach enables coordinated testing of both processors while maintaining debug chain integrity, regardless of whether both processors are present or one or both sockets are unpopulated.

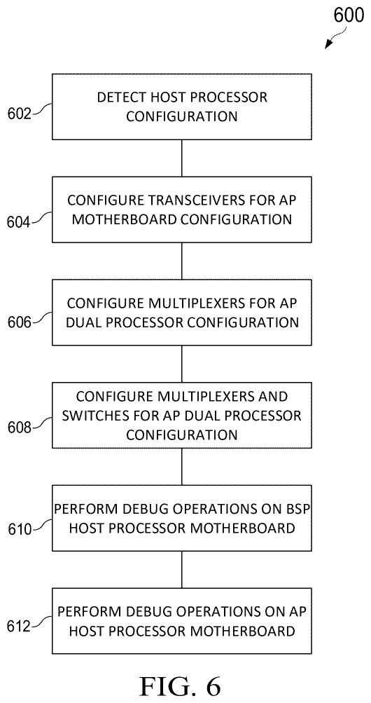

FIG. 6 illustrates a flowchart of an implementation method 600 for operating the host processor motherboard 300 as an AP motherboard in the dual motherboard configuration shown in FIG. 2. It is noted that all steps outlined in the method are not necessarily required and can be optional. Further, changes to the arrangement of the steps, removal of one or more steps and path connections, and addition of steps and path connections are similarly contemplated.

When operating as an AP motherboard, the host processor motherboard 300 serves as the second host processor motherboard 204. The first host processor motherboard 202 initiates the debug chain through the JTAG header 102 of the BSP motherboard, which provides the single debug interface for both motherboards. The JTAG signals are routed through the BSP motherboard to the AP motherboard. The AP motherboard's test data output (TDO) signals are then routed to the BSP motherboard through cable connection 206 coupled between the connector interface 108 of each motherboard to be read at the JTAG header 102 of the BSP motherboard.

At step 602, the first controller 302 and the second controller 308, in combination or individually, detect whether the host processor motherboard 300 is operating in a dual processor configuration. This detection can be based on configuration settings stored in the controllers, the absence of signals from the connector interface 108, or hardware strapping options on the motherboard. The detecting additionally includes determining whether the host processor motherboard 300 is operating as the first host processor motherboard 202 (BSP motherboard) or the second host processor motherboard 204 (AP motherboard). In some implementations, the controllers can receive a signal (not shown) from the JTAG header 102 that indicates the test configuration.

At step 604, depending on the determination at step 602, the first controller 302 configures the first transceiver 304 and the second transceiver 306 to disable JTAG signal routing from the JTAG header 102 to the processor socket 104, the first multiplexer 314, and the second multiplexer. The disabling isolates the JTAG header 102 of the AP motherboard since, in the dual processor configuration, the JTAG header of the BSP motherboard is used as the single debug interface for both motherboards.

At step 606, the first controller 302 configures the first multiplexer 314 and the second multiplexer 316 to route the main JTAG signals and the sideband signals from the connector interface 108, which is coupled to the first host processor motherboard 202 (i.e., the BSP motherboard). The first controller 302 sets the third control signal path 356 and the fourth control signal path 358 to configure the first multiplexer 314 and the second multiplexer 316, respectively, to allow JTAG signals to be routed from the connector interface 108.

At step 608, the second controller 308 configures the third multiplexer 318, the fourth multiplexer 320, and the fifth multiplexer 322 to establish the JTAG debug chain. The fifth multiplexer 322 of the AP motherboard is the main routing point for TDI and TDO signals from and to the BSP motherboard through the connector interface 108.

In implementations where the processor is present in the processor socket 104, the test data input (TDI)—which is the test data output (TDO) signal from the BSP motherboard—is routed from the connector interface 108 through the signal path 380 to the fifth multiplexer 322, through signal path 372 to the first switch 310, and finally through signal path 366 to the processor socket 104.

The AP processor's test data output (TDO) returns from the processor socket 104 through the signal path 370 to the second switch 312. The TDO signal of the AP processor of the AP motherboard is routed through the multiplexer network through connector interface 108.

In implementations where the processor is absent from the processor socket 104, the test data input (TDI)—which is the test data output (TDO) signal from the BSP motherboard—is routed from the connector interface 108 through the signal path 380 to the fifth multiplexer 322, through signal path 372 to the first switch 310. The second controller 308 configures the first switch 310 and the second switch 312 to create a bypass path. Accordingly, in the absence of the processor, the test data input (TDI) signal is provided as the test data output (TDO) signal to the second switch 312. The TDO signal, which has bypassed the processor socket 104 in the AP motherboard, is routed through the multiplexer network through connector interface 108.

At step 610, with the JTAG debug chain established through both motherboards, debug operations can be performed on the BSP and AP motherboards through the JTAG header 102 of the BSP motherboard. In implementations where the BSP processor is present in the processor socket 104, these operations may include examining processor registers, setting breakpoints, analyzing processor operations, or performing other debug functions on the BSP processor. The test clock (TCK) synchronizes the debug operations, while the test mode select (TMS) signal controls the test access port state machine. Test data is sent through the TDI signal path and results are received through the TDO signal path. In implementations where the BSP processor is absent, the established bypass path allows testing to continue through to the AP processor.

At step 612, debug operations continue to the AP motherboard via the connector interface 108. The TDI signals that traversed through (or bypassed) the BSP processor now enter the AP motherboard for debug operations. The AP motherboard's test responses return through the TDO path back to the JTAG header 102 of the BSP motherboard. This single debug interface approach enables coordinated testing of both processors while maintaining debug chain integrity, regardless of whether both processors are present or one or both sockets are unpopulated.

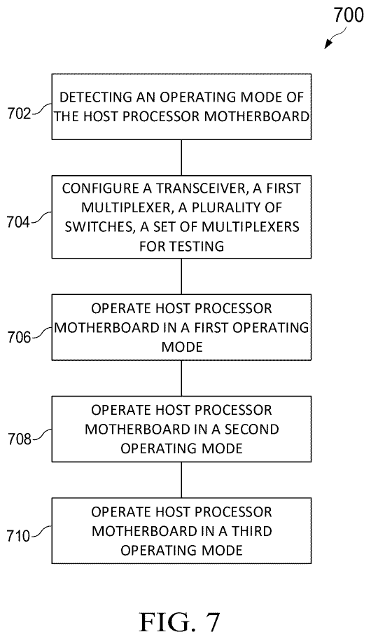

FIG. 7 illustrates a flowchart of an implementation method 700 for operating the host processor motherboard 300 in a test configuration. It is noted that all steps outlined in the method are not necessarily required and can be optional. Further, changes to the arrangement of the steps, removal of one or more steps and path connections, and addition of steps and path connections are similarly contemplated.

At step 702, the operating mode of the host processor motherboard is detected. This detection can be based on configuration settings stored in controllers, signals from a connector interface, or hardware strapping options on the motherboard.

In the first operating mode, the motherboard operates as a bootstrap processor (BSP) motherboard in a dual processor configuration. In the second operating mode, the motherboard operates in a single processor configuration. In the third operating mode, the motherboard operates as an application processor (AP) motherboard in the dual processor configuration.

At step 704, the components are configured for testing operations based on the operating mode. These components include a transceiver coupled between a JTAG header and a processor socket, a first multiplexer coupled between the transceiver and a connector interface, a plurality of switches coupled to the processor socket, and a set of multiplexers coupled between the plurality of switches and the JTAG header and between the plurality of switches and the connector interface.

At step 706, the host processor motherboard is configured in a first operating mode. In the first operating mode, the host processor motherboard operates as a bootstrap processor (BSP) motherboard in a dual processor configuration. In this mode, the JTAG header of the motherboard serves as the main debug interface for both processors, with JTAG signals traversing through the local processor before routing to and from a second host processor motherboard through the connector interface.

At step 708, the host processor motherboard is configured in a second operating mode. In the second operating mode, the host processor motherboard operates independently in a single processor configuration. The processor functions as a bootstrap processor that handles all processing tasks, with the JTAG header providing direct debug access without requiring signal routing to other motherboards. The connector interface remains isolated in this mode.

At step 710, the host processor motherboard is configured in a third operating mode. In a third operating mode, the host processor motherboard operates as an application processor (AP) motherboard in the dual processor configuration. In this mode, the JTAG header is isolated since debug signals are received from a BSP motherboard through the connector interface. The motherboard processes these signals through its local processor and returns test responses back to the BSP motherboard through the connector interface.

Although this disclosure describes or illustrates particular operations as occurring in a particular order, this disclosure contemplates the operations occurring in any suitable order. Moreover, this disclosure contemplates any suitable operations being repeated one or more times in any suitable order. Although this disclosure describes or illustrates particular operations as occurring in sequence, this disclosure contemplates any suitable operations occurring at substantially the same time, where appropriate. Where appropriate, any suitable operation or sequence described or illustrated herein may be interrupted, suspended, or otherwise controlled by another process, such as an operating system or kernel. The acts can operate in an operating system environment or as stand-alone routines occupying all or a substantial part of the system processing.

While this disclosure has been described with reference to illustrative implementations, this description is not intended to be construed in a limiting sense. Various modifications and combinations of the illustrative implementations, as well as other implementations of the disclosure, will be apparent to persons skilled in the art upon reference to the description. Therefore, the appended claims are intended to encompass any such modifications or implementations.

What is claimed is:

1. A computer system comprising a first host processor motherboard couplable to a second host processor motherboard, each host processor motherboard comprising:
a processor socket;
a connector interface configured to couple the first host processor motherboard to the second host processor motherboard;
a Joint Test Action Group (JTAG) header;
a transceiver coupled between the JTAG header and the processor socket;
a first multiplexer coupled between the transceiver and the connector interface;
a plurality of switches coupled to the processor socket;
a set of multiplexers coupled between the plurality of switches and the JTAG header and between the plurality of switches and the connector interface; and
a control circuit configured to control the routing of signals through the transceiver, the first multiplexer, the plurality of switches, and the set of multiplexers,
wherein in a first operating mode, the control circuit is configured to:
route JTAG signals from the JTAG header of the first host processor motherboard through both processor sockets,
route test data input signals from the JTAG header of the first host processor motherboard to the processor socket of the first host processor motherboard,
route test data output signals of the processor socket of the first host processor motherboard as test data input signals to the processor socket of the second host processor motherboard, and
route test data output signals of the processor socket of the second host processor motherboard to the JTAG header of the first host processor motherboard.

2. The computer system of claim 1, wherein, in the first operating mode, the control circuit is configured to route the JTAG signals to the processor socket of the first host processor motherboard and to the processor socket of the second host processor motherboard through the first multiplexer and the connector interface.

3. The computer system of claim 1, wherein, in the first operating mode, the control circuit is configured to route the test data input signals to the processor socket of the first host processor motherboard and the test data output signals of the first host processor motherboard to the processor socket of the second host processor motherboard as test data input signals through the plurality of switches and the set of multiplexers.

4. The computer system of claim 1, wherein, in a second operating mode, the control circuit is configured to:
route JTAG signals from the JTAG header of the first host processor motherboard through the first processor socket;
route test data input signals from the JTAG header of the first host processor motherboard to the processor socket of the first host processor motherboard; and
route test data output signals of the processor socket of the first host processor motherboard to the JTAG header.

5. The computer system of claim 1, wherein, in a third operating mode, the control circuit is configured to:
route JTAG signals from the connector interface of the first host processor motherboard to the processor of the first host processor motherboard;
route test data output signals from the connector interface to the processor socket of the first host processor motherboard; and
route test data output signals from the processor socket of the first host processor motherboard to the connector interface.

6. The computer system of claim 1, wherein each host processor motherboard further comprises an auxiliary transceiver and a second multiplexer to route sideband signals to the processor socket.

7. The computer system of claim 1, wherein, in response to no processor being seated in the processor socket, the control circuit is configured to route test data input signals through the plurality of switches to create a bypass path between an input of the processor socket and an output of the processor socket.

8. A non-transitory computer-readable medium storing instructions for operating a host processor motherboard that, when executed by a control circuit, cause the control circuit to:
detect an operating mode of the host processor motherboard;
configure a transceiver coupled between a Joint Test Action Group (JTAG) header and a processor socket;
configure a first multiplexer coupled between the transceiver and a connector interface;
configure a plurality of switches coupled to the processor socket; and
configure a set of multiplexers coupled between the plurality of switches and the JTAG header and between the plurality of switches and the connector interface,
wherein, in a first operating mode, the instructions cause the control circuit to:
route JTAG signals from the JTAG header through both the processor socket and a processor socket of a second host processor motherboard,
route test data input signals from the JTAG header to the processor socket,
route test data output signals of the processor socket as test data input signals to the processor socket of the second host processor motherboard, and
route test data output signals of the processor socket of the second host processor motherboard to the JTAG header.

9. The non-transitory computer-readable medium of claim 8, wherein, in the first operating mode, the instructions cause the control circuit to route the JTAG signals to the processor socket and to the processor socket of the second host processor motherboard through the first multiplexer and the connector interface.

10. The non-transitory computer-readable medium of claim 8, wherein, in the first operating mode, the instructions cause the control circuit to route the test data input signals to the processor socket and the test data output signals to the processor socket of the second host processor motherboard as test data input signals through the plurality of switches and the set of multiplexers.

11. The non-transitory computer-readable medium of claim 8, wherein, in a second operating mode, the instructions cause the control circuit to:
route JTAG signals from the JTAG header through the processor socket;
route test data input signals from the JTAG header to the processor socket; and
route test data output signals of the processor socket to the JTAG header.

12. The non-transitory computer-readable medium of claim 8, wherein, in a third operating mode, the instructions cause the control circuit to:
route JTAG signals from the connector interface to the processor socket;
route test data input signals from the connector interface to the processor socket; and
route test data output signals from the processor socket to the connector interface.

13. The non-transitory computer-readable medium of claim 8, wherein the instructions further cause the control circuit to configure an auxiliary transceiver and a second multiplexer to route sideband signals to the processor socket.

14. The non-transitory computer-readable medium of claim 8, wherein, in response to no processor being seated in the processor socket, the instructions cause the control circuit to route test data input signals through the plurality of switches to create a bypass path between an input of the processor socket and an output of the processor socket.

15. A method for operating a host processor motherboard, the method comprising:
detecting an operating mode of the host processor motherboard;
configuring a transceiver coupled between a Joint Test Action Group (JTAG) header and a processor socket;
configuring a first multiplexer coupled between the transceiver and a connector interface;
configuring a plurality of switches coupled to the processor socket; and
configuring a set of multiplexers coupled between the plurality of switches and the JTAG header and between the plurality of switches and the connector interface,
wherein, in a first operating mode, the method comprises:
routing JTAG signals from the JTAG header through both the processor socket and a processor socket of a second host processor motherboard,
routing test data input signals from the JTAG header to the processor socket,
routing test data output signals of the processor socket as test data input signals to the processor socket of the second host processor motherboard, and
routing test data output signals of the processor socket of the second host processor motherboard to the JTAG header.

16. The method of claim 15, wherein, in the first operating mode, the method comprises routing the JTAG signals to the processor socket and to the processor socket of the second host processor motherboard through the first multiplexer and the connector interface.

17. The method of claim 15, wherein, in the first operating mode, the method further comprises:
routing the test data input signals to the processor socket; and
routing the test data output signals to the processor socket of the second host processor motherboard as test data input signals through the plurality of switches and the set of multiplexers.

18. The method of claim 15, further comprising:
routing JTAG signals from the JTAG header through the processor socket;
routing test data input signals from the JTAG header to the processor socket; and
routing test data output signals of the processor socket to the JTAG header.

19. The method of claim 15, wherein, in a third operating mode, the method further comprises:
routing JTAG signals from the connector interface to the processor socket;
routing test data input signals from the connector interface to the processor socket; and
routing test data output signals from the processor socket to the connector interface.

20. The method of claim 15, further comprising configuring an auxiliary transceiver and a second multiplexer to route sideband signals to the processor socket.
